(19) United States
(12) Patent Application Publication
(10) Pub. No.: US 2013/0240015 A1
(43) Pub. Date: Sep. 19, 2013

(54) PORTABLE FOLDING SOLAR PANELS

(71) Applicants: Dan Chaimovski, Tel Aviv (IL); Reuven Marko, Netanya (IL); Yuval Shachar, Hertzlia Pituach (IL)

(72) Inventors: Dan Chaimovski, Tel Aviv (IL); Reuven Marko, Netanya (IL); Yuval Shachar, Hertzlia Pituach (IL)

(21) Appl. No.: 13/888,928

(22) Filed: May 7, 2013

Related U.S. Application Data
(63) Continuation of application No. PCT/IL2011/000857, filed on Nov. 3, 2011.
(60) Provisional application No. 61/411,230, filed on Nov. 8, 2010.

(51) Int. Cl. H01L 31/045

(52) U.S. Cl. CPC H01L 31/045
USPC 136/245

(57) ABSTRACT

A portable folding arrangement of panels apparatus is used for generation of power that may be regulated and supplied to a consumer of the generated power. In particular, such a power consumer may be an air-conditioner to be used, for example, within a vehicle, to control the temperature therein. The apparatus is comprised of a plurality of essentially rigid panels, each having at least a solar cell, that are connected to supply the power to charge a battery, to operate a power consumer, and the like. The plurality of panels are connected to allow the collapsing of the foldable panels face-to-face, back-to-back, or other folding arrangements. The apparatus can be unfolded when desired for the purpose of converting the solar energy into electrical power for storage or use by a power consumer.

### CROSS-REFERENCE TO RELATED APPLICATIONS

This application is a continuation application of International application No. PCT/IL2011/000857 filed on Nov. 3, 2011 which claims priority from U.S. provisional patent application No. 61/411,230, filed on Nov. 8, 2010, the contents of are incorporated herein by reference for all that they contain.

### TECHNICAL FIELD

The invention generally relates to a foldable arrangement of solar panels, and more specifically to such an arrangement which is foldable without the necessity of folding equipment and is portable thereafter.

### BACKGROUND

Solar panels, as a form for generation of clean energy, have been known now for decades. With the trend of providing energy from cleaner sources the use of solar panels is increasing in popularity. Other than during the manufacturing process, the panels do not create, during their lifetime of operation, any known environmental hazards and are able to provide, within known limits, power that may be used by power consumers or otherwise stored in power storage units, such as batteries, for future use.

Commonly solar panels are mounted rigidly in relatively large areas for the purpose of generation of energy. The solar panels may be placed, for example, on a roof top of a building to provide at least part of its energy consumption from a clean source of energy. Such panels maybe moveable such that the panels can track the moving sun both during its trip from east to west relative to earth on a daily basis as well as on the north to south and back motion relative to earth that occurs during the course of a year. Enabling such motion ensures better efficiency of the solar power, or in other words, the generation of additional energy.

At times it is desirable to have portable and/or foldable solar panels and certain prior art exists in this area. For example, U.S. Pat. No. 4,555,585 discusses a device which comprises a plurality of solar panels that can fold and unfold like an accordion, using a folding and unfolding system that is connected to the plurality of solar panels. While both portable and foldable, this solution is physically quite bulky solution and is primarily only suitable for the generation of relatively large amounts of energy at a relatively significant upfront cost. Hence, the objective of that solution is to be operational in space and was testable, rather than usable, on earth.

A more feasible solution for an application on earth is shown in US Patent Application Publication No. 2008/0223431 which shows a solution where it appears that the solar panels are placed on another material that is foldable, thereby allowing the folding of the unit about a plurality of axis, including a diagonal axis. However, the complexity of the design requires the use of rigid cell assemblies, and folding cell assemblies, as well as primary and secondary flexible seams. Some similar solutions allow the placing of the plurality of solar cells in transparent pockets of a flexible material, such as the one shown by Outfitter Satellite™ Inc.

It would be therefore advantageous to provide a solution that would allow for a portable folding solar panel apparatus which overcomes the deficiencies of the prior art. It would be further advantageous if such an apparatus would be able to provide the power necessary to operate, for example, a cooling instrument for a vehicle without relying on the energy sources available in the vehicle itself. It would be further advantageous if the solution would be light weight but still rigid enough to allow for true portability and transportability.

### BRIEF DESCRIPTION OF THE DRAWINGS

The disclosed subject matter is particularly pointed out and distinctly claimed in the claims at the conclusion of the specification. The foregoing and other objects, features, and advantages of the invention will be apparent from the following detailed description taken in conjunction with the accompanying drawings.

FIG. 1A is a front view diagram of a first apparatus according to the various embodiments disclosed herein.

FIG. 1B is a top view diagram of the first apparatus.

FIG. 2A is a diagram of the fully folded first apparatus.

FIG. 2B is a diagram of the partially folded first apparatus.

FIG. 3A is a front view diagram of a second apparatus according to one embodiment.

FIG. 3B is a side view diagram of the fully folded second apparatus.

FIG. 4 is a front view diagram of a third apparatus having a liquid crystal display.

FIG. 5 is a front view diagram of a fourth apparatus according to another embodiment.

FIG. 6 is a front view of a partially folded fourth apparatus.

FIG. 7 is a front view of a fully folded fourth apparatus.

FIG. 8 is a side view of a fully folded fourth apparatus.

FIG. 9 is a schematic block diagram of the electrical circuit for an apparatus implemented in accordance with one embodiment.

### DETAILED DESCRIPTION

The embodiments disclosed are only examples of the many possible advantageous uses and implementations of the innovative teachings presented herein. In general, statements made in the specification of the present application do not necessarily limit any of the various claimed inventions. Moreover, some statements may apply to some inventive features but not to others. In general, unless otherwise indicated, singular elements may be in plural and vice versa with no loss of generality. In the drawings, like numerals refer to like parts through several views.

Certain exemplary embodiments include an apparatus comprised of a portable folding arrangement of panels used for generation of power that may be regulated and supplied to a consumer of such power. In particular, such a power consumer may be an air-conditioner to be used, for example, within a vehicle, to control the temperature therein. The apparatus is comprised of a plurality of essentially rigid panels, each having at least a solar cell, which are connected so as to be able to supply the power to charge a battery and/or operate a power consuming device. The plurality of panels is connected to allow the collapsing of the foldable panels face-to-face, back-to-back, or other types of folding as the case may be. The apparatus can be unfolded when desired for the purpose of converting the solar energy into electrical power for storage or use by a consumer of power. A plurality of embodiments is shown.

According to various disclosed embodiments, a plurality of panels is provided, each solar panel includes of at least a solar cell that is comprised a plurality of photovoltaic cells. The at least a solar cell is embedded in a panel that is made of an essentially transparent material such as, but not limited to, durable glass, plastic, and the like. The resultant panel is now rigid enough and durable enough to perform the functions of the described apparatus. The panel may be shaped to accommodate the desired applications, examples of which are provided herein below.

In one embodiment, each panel is designed to fit either directly or by other means on opposite sides of each panel, in an accordion like fashion, and as described in more detail herein below, to allow the pivoting around the fitting point such that the panels may be folded either face-to-face or back-to-back in an accordion like fashion. When unfolded the plurality of panels may be positioned to face the sun and perform energy conversion, the size of the unfolded apparatus being a multiplication of the width of a panel times the number of panels in the apparatus. The thickness of the unfolded apparatus is essentially that of a single panel. When folded the size of the folded apparatus is the width and length of a single panel and the thickness essentially is a multiplication of the number of panels by the thickness of a single panel. The panels are, for example, electrically connected to each other to provide the desired level of energy.

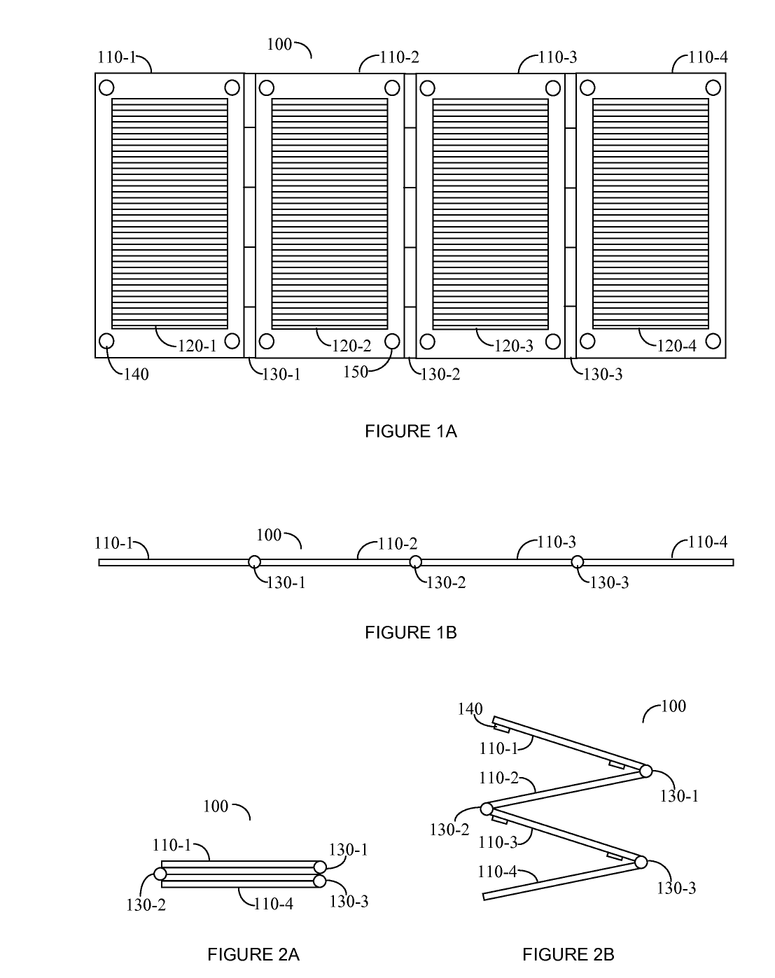

In one embodiment, a voltage regulator is embedded into at least one of the panels. In yet another embodiment, a charger is embedded into at least one of the panels. In yet another embodiment a liquid crystal display is embedded into at least one panel of the apparatus for the purpose of enabling a desired display (LCD), for example advertisements, over the solar panel. Other display technologies are also possible, for example and not by way of limitation, an organic light emitting diodes (OLED) display. Other folding solutions may be used depending on the specific application and examples are described below. These embodiments are further described below in greater detail. Reference is now made to FIG. 1A which depicts an exemplary and non-limiting front view diagram of a first apparatus 100 implemented according to one embodiment, as well as FIG. 1B which depicts a top view diagram of the first apparatus 100. The apparatus 100 comprises a plurality of panels 110, for example panels 110-1, 110-2, 110-3 and 110-4. The panels 110 are affixed to each other by a connecting means that enables any two panels 110 to fold against each other. For example, panel 110-1 may fold against panel 110-2 face-to-face over a pivot 130-1 while panel 110-2 folds against panel 110-3 back-to-back over a pivot 130-2, and so on and so forth, to achieve an accordion like folding.

Each panel 110 further comprises at least a solar cell 120, and it should be understood that a plurality of solar cells is also possible. Each solar cell 120 is comprised of photovoltaic cells that convert solar energy into electrical energy. The panels are, for example, electrically connected to each other so as to provide a point of output of the electrical energy. In one embodiment, one of the panels, for example panel 120-4 may further contain a voltage regulator circuit (not shown) for providing regulated voltage to a power consumer. In yet another embodiment, a charger circuit (not shown) may be embedded into one of the panels, for example panel 120-4, to enable the charging of a power storage device, for example a battery. In yet another embodiment a dedicated panel containing only the support circuitry is affixed to at least one of the panels 110.

Each panel may optionally have at least one of a connector depression 150 or connector protrusion 140 wherein the connector protrusion 140 fits inside the connector depression 150 to ensure that the panels are locked to each other when in a folded position. Such an exemplary and non-limited folded position is shown with respect of FIG. 2A. It should be noted that the same kind of connectors may similarly be placed at the back of each panel to ensure that when panels are folded back-to-back such that locking tension is achieved.

FIG. 2B shows a diagram of the partially folded panels 110 of the apparatus 100. According to an embodiment, the pivots 130, shown as 130-1, 130-2 and 130-3 also have fastening capabilities to ensure fixation at one or more desired lock positions. When moving from a desired lock position additional force may be necessary in order to disengage from the lock position. This ensures that the panels are firmly positioned in a desired position which, for example, may be important when placing, for example, the apparatus 100 in a windshield of a car. In such a case the apparatus 100 may feed, for example, into a direct current (DC) air-conditioner unit (ACU) for the purpose of cooling a car while parked so as to ensure that the interior temperature of the car is maintained at a pleasant level without depleting the car's main battery.

In one embodiment, a control circuit may be further embedded in at least one of the panels to disable the operation of the ACU if the voltage of a battery connected to the apparatus 100 drops below a predetermined level. In one embodiment a timer may be used to ensure the cooling process is started is started more closely to the expected return time to the vehicle, and that a battery is being charged during any intervening such time.

A person skilled in the art would of course readily appreciate that other applications and usages of the portable folding solar panels apparatus 100 can provided based on the disclosed teachings.

The panels 110 are to be made of an essentially transparent material, such as durable glass or various types of plastic or similar materials. The transparency should be such that, when embedding the solar cells 120 in a panel 110, sufficient amounts of light are able to go through the panel material to maintain overall efficiency of the conversion of solar energy into electrical energy. It is further desirable for the panels to be sufficiently thin and lightweight enough to enable a person to handle a plurality of panels without requiring additional help. As noted above, support circuitry such as a charger circuit of a regulator circuit may be embedded in at least one of the panels. The back side of the panels 110 maybe coated to provide additional shading capabilities which may be useful in the case of, for example, a vehicle using the apparatus 100 for the purpose of cooling the interior of the vehicle.

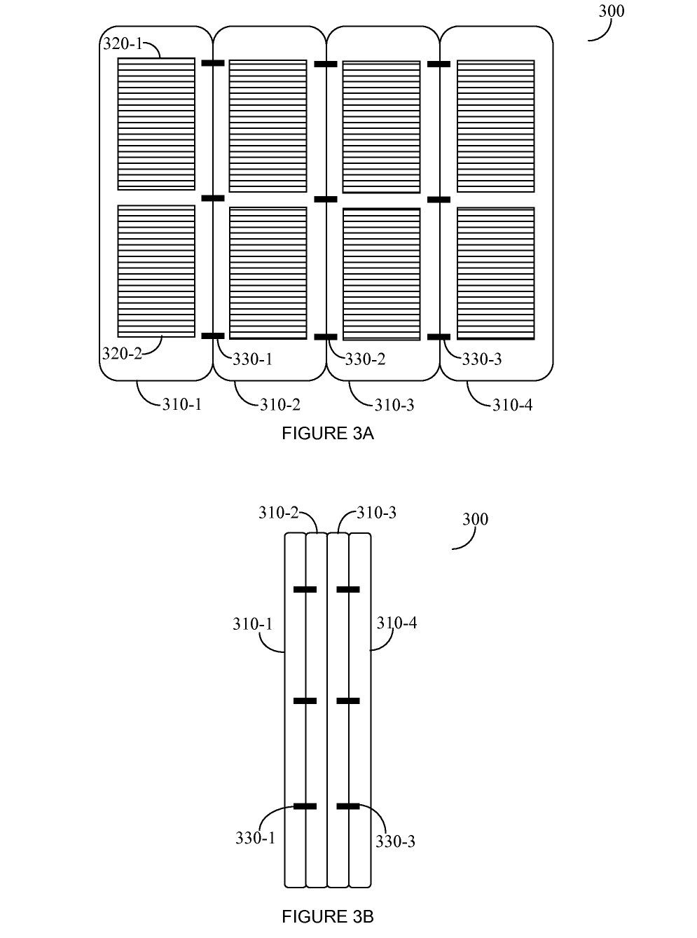

FIG. 3A depicts an exemplary and non-limiting front view diagram of a second apparatus 300 according to one embodiment and FIG. 3B shows a side view diagram of the fully folded second apparatus 300. Similar to the apparatus 100 described hereinabove, apparatus 300 comprises a plurality of panels 310, for example 310-1, 310-2, 301-3 and 310-4, connected to each other by hinges 330 that enable the folding of the panels either back-to-back or face-to-face as the case may be.

Each panel 310 has solar cells 320 embedded in it, for example 320-1 and 320-2. These cells are electrically connected, for example, to each other and therefrom to the other panels 310 to provide the overall energy of the apparatus 300. It should be noted that the specific use of these hinges are merely provided to demonstrate that other ways for implementing the apparatus 300.

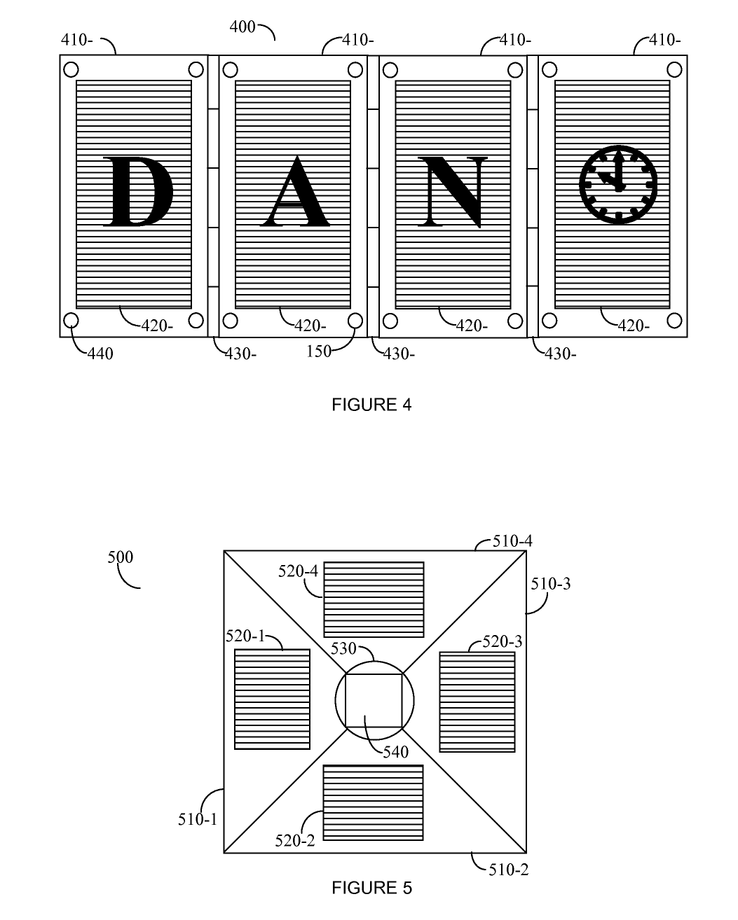

FIG. 4 shows an exemplary and non-limiting front view diagram of a third apparatus 400 having a liquid crystal display (LCD) constructed according to another embodiment. The integration of the LCD capabilities with the panels 410 may take various forms. The LCD may be part of the solar cell itself, as demonstrated, for example, in U.S. Pat. No. 6,323,923, or may be embedded in the panel 410 in areas above the solar cells 420 or in areas underneath in which no solar cells 420 are present. Furthermore, LCD panels may be embedded at the back of the solar panel.

The LCD may be powered by the solar energy converted into electric energy and thereby may provide a means for displaying, for example, advertisements on the panels 410. Circuitry for loading content for the LCD may be embedded in the panel 410 in the same manner that other circuits are embedded therein. However, in one embodiment, a read-only memory (ROM) or otherwise any kind of other non-volatile memory (NVM) may be used in conjunction with the circuitry of the LCD panel to provide the content to be displayed on the LCD panel. In addition to this kind of advertisement, it is also envisioned that the surfaces of the panels may be used for the purpose of printing in partially transparent print so that while solar energy can reach the solar cells there will be still visible characters and/or drawings and/or pictures shown on the panels.

Reference is now made to FIGS. 5, 6, 7 and 8 which depict an exemplary and non-limiting fourth apparatus 500 implemented in accordance with the disclosed embodiments. The apparatus 500 is comprised of four panels 510-1, 510-2, 510-3 and 510-4, each in the exemplary form of essentially a triangle, such that when in the position shown in FIG. 5 a square is created. A person with ordinary skill in the art would readily appreciate that any other number of panels, as well as a variety of other shaped panels may be used.

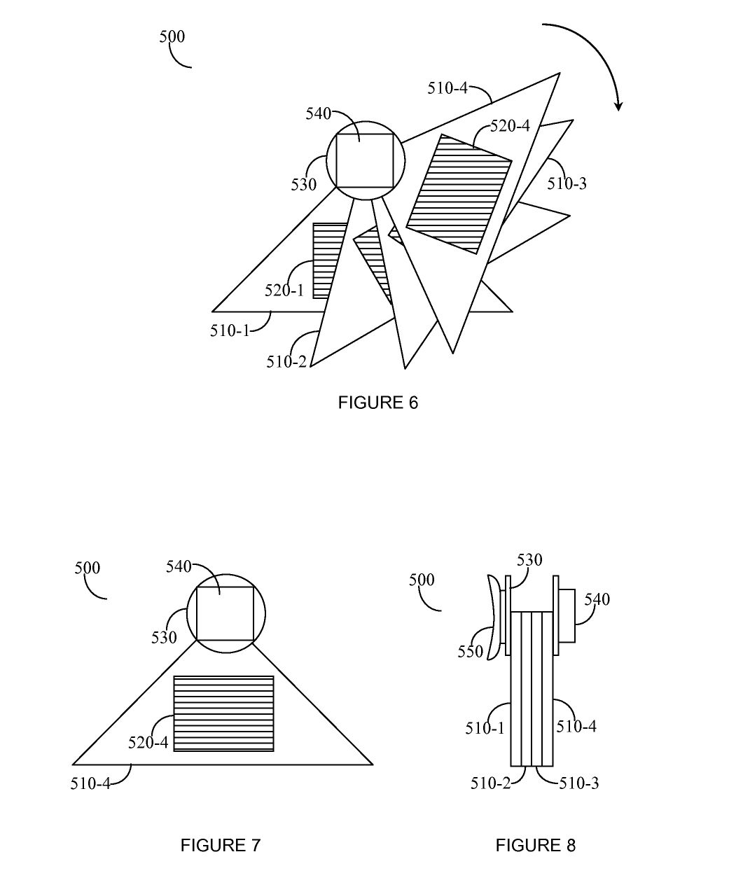

The apparatus 400 is further equipped with a binder 530 that allows the motion of the panels to collapse over each other, as shown for example in FIG. 6 with respect of apparatus 500. The binder 530 is further equipped with electric connections to be used as further explained below. The panels 510-1 through 510-4 are equipped with at least one corresponding solar cell 520-1 through 520-4 respectively. The solar cells 520 convert solar energy into electrical energy that is transferred through wires embedded in the panels 510 to the electric connections in the binder 530. The binder 530, using electric leads (not shown), provides the electric current to an appropriate circuit housed in a housing 540, from which the electric power can be used. The housing 540 may further contain a battery or another power storage device to store energy not consumed by a power consumer connected to the apparatus 500. FIG. 7 depicts a front view of a fully folded apparatus 500 according to an embodiment. FIG. 8 further shows the apparatus 500 equipped with a suction cup 550 to enable the affixing of the apparatus 500 onto a surface such as the windshield or window of a vehicle.

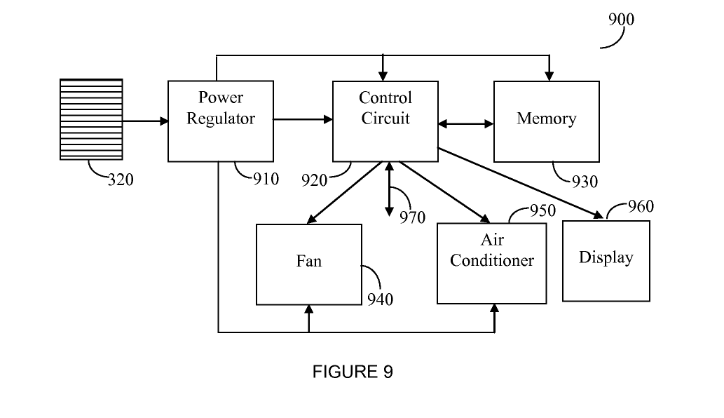

FIG. 9 shows an exemplary and non-limiting schematic block diagram 900 of the electrical circuit for a sunshade, e.g., the umbrella discussed in greater detail hereinabove. The solar cells 320 feed a power regulator 910 which generates one or more supply voltages as may be necessary. The power regulator 910 provides the power to the elements of the circuit.

A control circuit 920, which may be comprised of a microprocessor or microcontroller, is connected to a memory 930 which may store a plurality of instructions for the control of other parts of the circuit. The memory 930 may further contain content uploaded to the memory via, for example, interface 970. The control circuit 920 controls the operation of the fan 940 and the optional air conditioner 950. A display 960 connected to the control circuit 920 and optionally coupled to the memory 930 allows the display of content from the memory 930 under the control of the control circuit 920. The electrical circuit 900 may be integrated fully or partially in one of the panels, in a housing attached to at least one of the panels, or otherwise be electrically connected to the panels, as the case may be. Other embodiments are also possible in accordance with the disclosed embodiments.

In one embodiment, a version of the third apparatus described with respect of FIGS. 5-8 is used. In this embodiment the suction cup 550 is to be placed at a corner of a windshield of a vehicle, for example but without limitation, at the lower left corner of the windshield. The plurality of panels 310, each being essentially narrow, and having different lengths, may open to 90 degrees from a folded position to cover an essential rectangular area of the windshield. Typically, such an apparatus will cover one half of the windshield while a symmetrical apparatus placed on the other side of the windshield covers the second half of the windshield. The two apparatuses may be electrically coupled to provide the desired level of electrical power.

In yet another embodiment, use is made of photovoltaic cells that are embedded into a scrollable sheet. A canister is used to allow the scrollable sheet to either roll into the canister or be pulled outside of the canister and connect to the windshield in a secure manner. The scrollable sheet is electrically connected to a power regulator housed, for example, in the canister, to provide the desired regulated voltage from the scrollable sheet.

All examples and conditional language recited herein are intended for pedagogical purposes to aid the reader in understanding the teachings, embodiments, and the concepts contributed by the inventor to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

What is claimed is:

1. An apparatus for providing electrical power from solar energy, comprising:
a plurality of panels, each of the panels contain at least one solar cell;
a mechanism connecting each two adjacent panels of the plurality of panels, the mechanism having at least a first position to lock the panels in an unfolded position and at least a second position to lock the panels in a folded position; and
electrical paths for electrically connecting the at least a solar cell of each of the plurality of panels for the purpose of supplying an unregulated voltage resulting from the transfer of solar energy into electrical energy by the at least one solar cell.

2. The apparatus of claim 1, further comprising:
a voltage regulator embedded in at least one of the panels, the voltage regulator providing a regulated voltage as an output of the apparatus.

3. The apparatus of claim 1, further comprising:
a display integrated into at least one of the plurality of panels and receiving power supply for operation by being coupled to the at least one solar cell; and
a control circuit for controlling displayable content to be displayed on the display.

4. The apparatus of claim 3, wherein the display is any one of: a liquid crystal display (LCD) and an organic light emitting diode (OLED) display.

5. The apparatus of claim 3, wherein the control circuit comprises a memory for storing the displayable content.

6. The apparatus of claim 5, wherein the control unit further comprises an interface for loading the memory with the displayable content.

7. The apparatus of claim 1, further comprising:
an air conditioner receiving power supply for operation by being coupled to the at least one solar cell.

8. The apparatus of claim 1, further comprising:
means for affixing the apparatus to a windshield of a vehicle.

9. An apparatus for providing electrical power from solar energy, comprising:
a plurality of panels, each of the panels contain at least a solar cell;
a binder connecting the plurality of panels allowing the plurality of panels to swivel around the binder and having a first unfolded position exposing the at least one solar cell of each of the plurality of panels and having a second folded position where the plurality of panels cover each other to block the least one solar cell from the solar energy; and
electrical paths for electrically connecting the at least one solar cell of each of the plurality of panels for the purpose of supplying an unregulated voltage resulting from the transfer of solar energy into electrical energy by the at least a solar cell.

10. The apparatus of claim 9, further comprising:
a housing attached to the binder for storing an electrical circuit connected to the electrical paths, the electrical circuit comprising at least a voltage regulator.

11. The apparatus of claim 10, further comprising:
a display integrated into at least one of the plurality of panels and receiving power supply for operation by being coupled to the at least one solar cell; and
a control circuit in the housing for the purpose of controlling displayable content to be displayed on the display.

12. The apparatus of claim 11, wherein the display is any one of: an liquid crystal display (LCD) and an organic light emitting diode (OLED) display.

13. The apparatus of claim 11, wherein the control circuit comprises:
a memory for storing the displayable content; and
an interface for loading the memory with the displayable content.

14. The apparatus of claim 9, further comprising:
an air conditioner receiving power supply for the operation by being coupled to the at least a solar cell.

15. The apparatus of claim 9, further comprising:
means for affixing the apparatus to a windshield of a vehicle, the means for affixing the apparatus being connected to the binder.

16. The apparatus of claim 9, wherein the plurality of panels are of different lengths such that when the plurality of panels are in the the unfolded position the most extended panel of the plurality of panels is ninety degrees from a stationary panel of the plurality of panels and wherein the unfolded position covers an essentially rectangular area.

17. An apparatus for providing electrical power from solar energy, comprising:
a photovoltaic foldable sheet;
a canister for housing the photovoltaic foldable sheet, wherein t the photovoltaic foldable sheet is fully contained in the canister in a folded position and is essentially outside of the canister connected at one side of the photovoltaic foldable sheet to the canister to expose the photovoltaic cells to the solar energy; and
electrical paths for electrically connecting the photovoltaic foldable sheet for the purpose of supplying an unregulated voltage resulting from the transfer of solar energy into electrical energy by the at least one solar cell.

18. The apparatus of claim 17, further comprising:
a voltage regulator connected to the electrical paths for the purpose of regulating the power supplied from the photovoltaic foldable sheet.

19. The apparatus of claim 17, wherein at least a portion of the foldable sheet is a display.

20. The apparatus of claim 20, wherein the display is any one of: a liquid crystal display (LCD) and an organic light emitting diode (OLED) display.
